(19) United States
(12) Patent Application Publication
(10) Pub. No.: US 2023/0069546 A1
(43) Pub. Date: Mar. 2, 2023

(54) SEMICONDUCTOR DEVICE

(71) Applicant: SANKEN ELECTRIC CO., LTD., Niiza-Shi (JP)

(72) Inventor: Toru YOSHIE, Hino-Shi (JP)

(73) Assignee: SANKEN ELECTRIC CO., LTD., Niiza-Shi (JP)

(21) Appl. No.: 17/411,389

(22) Filed: Aug. 25, 2021

(51) Int. Cl. H01L 29/16; H01L 29/04

(52) U.S. Cl. CPC H01L 29/1608; H01L 29/04

(57) ABSTRACT

A semiconductor device according to one or more embodiments is disclosed that may include a first substrate comprising a single-crystalline SiC substrate; a second substrate comprising a polycrystalline SiC substrate; and an interface layer sandwiched between the first substrate and the second substrate and comprising at least elements of phosphorus and chromium.

### BACKGROUND

The present disclosure relates to a semiconductor device containing silicon carbide (hereinafter referred to as SiC), and in particular to a SiC semiconductor device in which the current flows perpendicular to a substrate.

SiC is widely used as a material for semiconductor devices, not only because of its excellent corrosion resistance and heat resistance, but also because of its excellent electrical features. Japanese Patent Publication 2012-146694 (Patent Document 1) discloses a vertical semiconductor device substrate using SiC. This semiconductor device substrate includes a support substrate and single-crystalline SiC bonded to the support substrate. The support substrate includes a substrate including a material with lower resistivity than that of single-crystalline SiC and a SiC thin film covering the substrate. In the technology described in Patent Document 1, the electrical resistance becomes high at the junction interface between the single-crystalline SiC and the substrate, which may result in a decrease in the current characteristics flowing perpendicular to the substrate.

### SUMMARY

A semiconductor device according to one or more embodiments may include a first substrate comprising a single-crystalline SiC substrate; a second substrate comprising a polycrystalline SiC substrate; and an interface layer sandwiched between the first substrate and the second substrate and comprising at least elements of phosphorus and chromium.

### BRIEF DESCRIPTION OF DRAWINGS

FIG. 1 is a diagram illustrating a cross-sectional view of a semiconductor device according to one or more embodiments;

FIG. 2 is a flowchart illustrating a manufacturing method of a semiconductor device according to one or more embodiments; and

FIGS. 3A, 3B, 3C, and 3D are diagrams illustrating steps of a manufacturing process of a semiconductor manufacturing method according to one or more embodiments.

### DETAILED DESCRIPTION

A semiconductor device according to one or more embodiments and manufacturing method thereof are described with reference to the drawings.

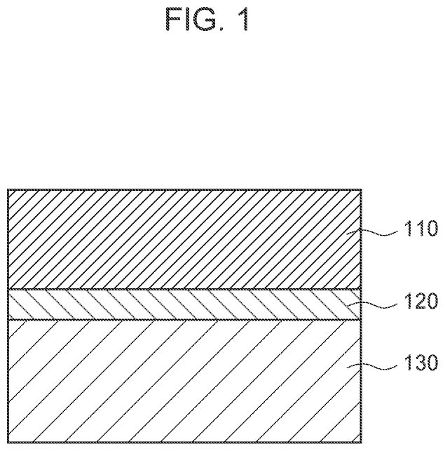

FIG. 1 is a diagram illustrating a cross-sectional view of a semiconductor device according to one or more embodiments. The semiconductor device includes a first substrate 110 having single-crystalline SiC as a main component, a second substrate 130 having polycrystalline SiC as a main component, and an interface layer 120 provided at the interface between the first substrate 110 and the second substrate 130.

The first substrate 110 may be mainly composed of a compound semiconductor in which two or more elements are combined, or may be mainly composed of SiC. The first substrate 110 may be formed by single-crystalline SiC having a structure in which the direction of the crystal axis does not change regardless of the position of the crystal, such as 3C—SiC crystal, 4H—SiC crystal, 6H—SiC crystal, 8H—SiC crystal, 10H—SiC crystal, 15R—SiC crystal, etc. Single-crystalline SiC may be manufactured by the gas phase method, solution method, or the Acheson method. In the solution method, carbon (C) is melted in a silicon (Si) melt or an Si alloy melt in a container such as a crucible. Single-crystalline SiC may be produced by a process in which SiC is grown by depositing a SiC crystal layer on a seed crystal substrate placed in the container. The first substrate 110 may include impurities other than single-crystalline SiC. The first substrate 110 may contain no impurities other than single-crystalline SiC. The first substrate 110 may preferably include a first transition element, especially single-crystalline SiC containing chromium (Cr). The thickness of the first substrate 110 may preferably be from 0.1 μm to 5 μm, and more preferably from 0.3 to 1 μm in terms of crystalline quality of the first substrate 110.

The interface layer 120 is positioned in between the first substrate 110 and the second substrate 130 and is provided at the interface between the first substrate 110 and the second substrate 130. The interface layer 120 may be mainly composed of a compound semiconductor in which two or more elements are combined, or may be mainly composed of SiC. The interface layer 120 may include single-crystalline SiC with phosphorus (P). The interface layer 120 may be formed by ion implantation of impurities, such as phosphorus (P), arsenic (As), and nitrogen (N), on the surface of the first substrate 110. In this case, an impurity concentration of 1×10¹⁹ atoms/cm³ to 1×10²² atoms/cm³ may be preferable for phosphorus, and 1×10²⁰ atoms/cm³ to 5×10²¹ atoms/cm³ may be more preferable in terms of decreasing resistance of the interface layer 120. For the thickness of the interface layer 120, 500 Å to 5000 Å may be preferable, and 1000 Å to 3000 Å may be more preferable in terms of decreasing resistance of the interface layer 120. The interface layer 120 may contain impurities to reduce the interfacial resistance between the first substrate 110 and the second substrate 130. When the first substrate 110 contains chromium and the interface layer 120 is formed by ion implantation of phosphorus (P) on the surface of the first substrate 110, the concentration of phosphorus may be preferably higher than the concentration of chromium contained in the first substrate 110. The interface layer 120 may include an alloy of chromium and phosphorus (CrP alloy), and the composition ratio of chromium and phosphorus may be preferably from 3:1 to 1:2, and 1:1 may be more preferable in terms of forming stable alloy and decreasing resistance of the interface layer 120.

The second substrate 130 may include a compound semiconductor in which two or more elements are combined, or may include SiC. The second substrate 130 may include polycrystalline SiC that contains a plurality of crystallites and has a structure in which the direction of the crystal axis of each crystallite may be different. The polycrystalline SiC may include a 4H—SiC crystal, a 6H—SiC crystal, an 8H—SiC crystal, a 10H—SiC crystal, a 15R—SiC crystal, or a mixture containing multiple of these crystals. The second substrate 130 may contain predetermined impurities other than polycrystalline SiC, or may contain no impurities at all. The second substrate 130 may include polycrystalline SiC containing nitrogen (N). The thickness of the second substrate 130 may be preferable from 100 to 1000 μm, and 300 to 800 μm may be preferable in terms of durability of the substrate.

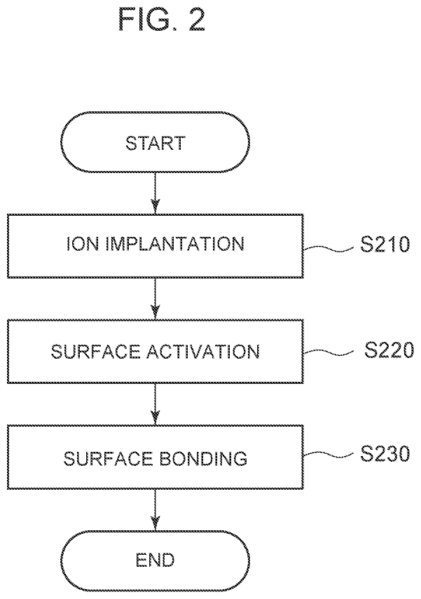

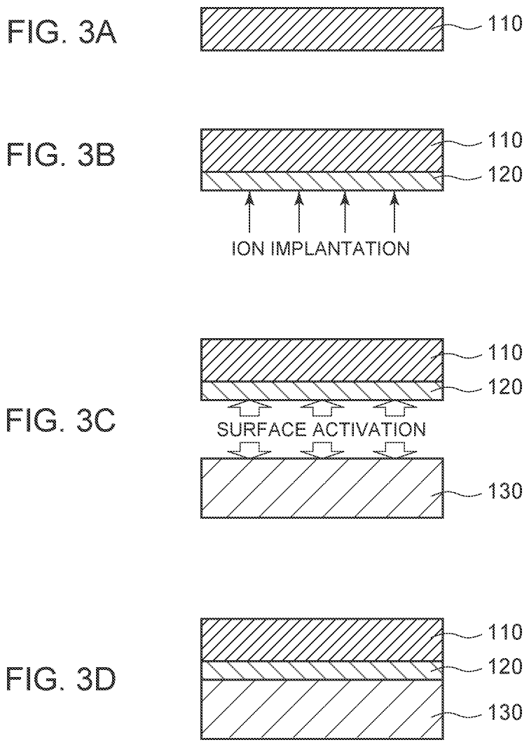

A method of manufacturing a semiconductor device according to one or more embodiments is described with reference to the drawings. FIG. 2 is a flowchart illustrating a manufacturing method of a semiconductor device for one or more embodiments. FIGS. 3A, 3B, 3C, and 3D are diagrams illustrating a manufacturing process of a semiconductor manufacturing method for one or more embodiments.

In step S210, ionized impurities are implanted into the first substrate 110. The first substrate 110 that has undergone pretreatment for ion implantation, such as surface planarization, is prepared (FIG. 3A). The first substrate 110 may be preferable to contain the first transition element, and in particular, single-crystalline SiC containing chromium (Cr) may be preferable. Ion implantation is performed on the surface of the first substrate 110 (FIG. 3B). As impurities to be implanted, phosphorus (P), arsenic (As), nitrogen (N), etc. may be used, and phosphorus may be preferable. In the ion implantation process, an acceleration energy of 10 keV to 100 keV may be preferable, and 10 KeV to 60 keV may be more preferable in terms of decreasing resistance of the first substrate 110. For the impurity concentration, over 1×10¹⁹/cm³ may be preferable, and over 1×10²⁰/cm³ may be more preferable in terms of decreasing resistance of the first substrate 110. For example, the interface layer 120 with a thickness of 1000 A may be formed under the conditions of an acceleration energy of 10 KeV and concentration of 1×10²⁰/cm³. As a result, the interface layer 120 containing, for example, chromium and phosphorus is formed on the surface of the first substrate 110.

In a step S220, an activation process of the surfaces of the first substrate 110 and the second substrate 130 is performed. In an embodiment, the activation process is performed on the surface of the interface layer 120 formed on the substrate 110. For example, gas is ionized by high-frequency plasma in a high vacuum or an ultrahigh vacuum and irradiated to the surface of the interface layer 120 formed on the first substrate 110 and the surface of the second substrate 130. This irradiation removes oxidized films, adhesives, etc. that may exist on the surfaces of the interface layer 120 and the second substrate 130 and activates the surfaces (FIG. 3C). The removal of the oxide film, adhesives, etc. may expose the dangling bonds of the surface atoms. Here, the gas includes inert gases such as argon (Ar), neon (Ne), xenon (Xe), etc.

In step S230, the surface of the interface layer 120 and the surface of the second substrate are bonded in a vacuum and then, baked at the temperature over 1500° C. (FIG. 3D).

The semiconductor device manufactured in this method can reduce the electrical resistance of the interface between the first substrate 110 and the second substrate 130, for example, by forming the interface layer 120 containing chromium and phosphorus at the interface between the first substrate 110, which is a single-crystalline substrate, and the second substrate 130, which is a polycrystal substrate. As a result, a semiconductor device with a good current characteristic in the direction across the interface can be provided.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A semiconductor device comprising:
a first substrate comprising a single-crystalline SiC substrate;
a second substrate comprising a polycrystalline SiC substrate; and
an interface layer sandwiched between the first substrate and the second substrate and comprising at least elements of phosphorus and chromium.

2. The semiconductor device according to claim 1, wherein
the interface layer comprises single-crystalline SiC.

3. The substrate according to claim 1, wherein
the interface layer has a thickness of 500 Å to 5000 Å.

4. The substrate according to claim 1, wherein
the interface layer has a thickness of 1000 Å to 3000 Å.

5. The semiconductor device according to claim 1, wherein
the first substrate comprises chromium.

6. The semiconductor device according to claim 1, wherein
the second substrate comprises nitrogen.

7. The semiconductor device according to claim 1, wherein
the interface layer has a higher concentration of phosphorus than that of chromium.

8. The semiconductor device according to claim 1, wherein
the interface layer contains an alloy of chromium and phosphorus.

9. The semiconductor device according to claim 8, wherein
the interface layer comprises an alloy of chromium and phosphorus with a composition ratio of 1:1.

10. The semiconductor device according to claim 1, wherein
the first substrate comprises a substrate manufactured by a solution method.

11. A substrate comprising:
a first layer comprising a single-crystalline SiC substrate;
a second layer comprising a polycrystalline SiC substrate; and
an interface layer sandwiched between the first layer and the second layer and comprising at least elements of phosphorus and chromium.

12. The substrate according to claim 11, wherein
the interface layer comprises single-crystalline SiC.

13. The substrate according to claim 11, wherein
the interface layer has a thickness of 500 Å to 5000 Å.

14. The substrate according to claim 11, wherein
the interface layer has a thickness of 1000 Å to 3000 Å.

15. The substrate according to claim 11, wherein
the first substrate comprises chromium.

16. The substrate according to claim 11, wherein
the second substrate comprises nitrogen.

17. The substrate according to claim 11, wherein
the interface layer has a higher concentration of phosphorus than that of chromium.

18. The substrate according to claim 11, wherein
the interface layer contains an alloy of chromium and phosphorus.

19. The substrate according to claim 18, wherein
the interface layer comprises an alloy of chromium and phosphorus with a composition ratio of 1:1.

20. The substrate according to claim 11, wherein the first substrate comprises a substrate manufactured by a solution method.
